(19) United States
(12) Patent Application Publication
(10) Pub. No.: US 2012/0025198 A1
(43) Pub. Date: Feb. 2, 2012

(54) THIN FILM TRANSISTOR ARRAY SUBSTRATE

(76) Inventor: Shiuan-Yi Ho, Hualien County (TW)

(21) Appl. No.: 12/983,327

(22) Filed: Jan. 3, 2011

(30) Foreign Application Priority Data
Jul. 29, 2010 (TW) 099214513

(51) Int. Cl. H01L 27/15

(52) U.S. Cl. 257/72; 257/E27.121

(57) ABSTRACT

A thin film transistor array substrate includes a substrate having a plurality of pixel units arranged in a matrix, a plurality of first gate lines and second gate lines alternately arranged on the substrate, a plurality of source lines perpendicular to the first gate lines and the second gate lines formed on the substrate, and a plurality of thin film transistors respectively positioned in the pixel units. Each of the source lines further includes a main source line and a sub source line electrically connected to each other in parallel connection.

### BACKGROUND OF THE INVENTION

1. Field of the Invention

The present invention is related to a thin film transistor (TFT) array substrate, and more particularly, to a TFT array substrate with dual gate design.

2. Description of the Prior Art

A conventional liquid crystal display (LCD) panel comprises a TFT array substrate and a color filter array substrate opposite to each other, and a liquid crystal layer positioned between the TFT array substrate and the color filter array substrate. Moreover, the TFT array substrate comprises a plurality of TFTs arranged in a matrix, as well as a plurality of gate lines and a plurality of source lines electrically connected to the TFTs. Furthermore, the color filter array substrate at least comprises a plurality of color filters for displaying colorful images, and a black matrix for preventing the leakage of light.

Based on different driving modes, the LCD panels can be classified as: single-gate type display panels and dual-gate type display panels. Please refer to FIG. 1 and FIG. 2, wherein FIG. 1 and FIG. 2 illustrate a TFT array substrate of a conventional normally white display panel with dual gate design. As shown in FIG. 1, the TFT array substrate 100 comprises a substrate, a plurality of gate lines G1, G2 . . . G7, and a plurality of source lines S1, S2, S3. In addition, the TFT array substrate 100 further includes a plurality of TFTs (G1, S1), (G2, S1), . . . , (G5, S3) . . . (G6, S3) and a plurality of pixel units. Each of the TFTs (G1, 51), (G2, 51), . . . , (G5, S3) . . . (G6, S3) and each of the pixel units are respectively located on the intersections of the gate lines G1, G2 . . . , G7 and the source lines S1, S2, S3. Moreover, referring to FIG. 1, each of the TFTs located on the left side of one of the source lines S1, S2, S3 is electrically connected to one of the odd gate lines G1, G3, G5 respectively; each of the TFTs located on the right side of one of the source lines S1, S2, S3 is electrically connected to one of the even gate lines G2, G4, G6. In other words, the TFTs located on the same row and separately located on the opposite sides of one of the source lines S1, S2, S3 share the corresponding one of the source lines S1, S2 or S3, but are electrically connected to different gate lines.

Since liquid crystal is utilized as the material to control display images for LCD panels, the electric polarity of source signals has to be inversed periodically in order to avoid the damage to the liquid crystal molecules caused by of the electric polarity under a fixed voltage that might cause image sticking. Several inversion driving methods have been proposed to drive the liquid crystal molecules for conventional LCD panels, such as frame inversion, line inversion, column inversion, dot inversion, or 2-dot inversion as shown in FIG. 1. In FIG. 1, “+” represents a positive polarity, and “−” represents a negative polarity. As shown in FIG. 1, the pixel units and TFTs located on the same row and separately on the opposite sides of one of the source lines S1, S2, S3 carry the same electric polarity, for example, the TFTs (G1, S1) and (G2, S1) separately located on the opposite sides of the source line S1 carry a positive polarity. In addition, the pixel units and TFTs located on the same row and separately on the opposite sides of any adjacent two of the source lines carry opposite polarities. For example, the TFTs (G1, S1) and (G2, S1) located on the opposite sides of the source line S1 carry a positive polarity, while the TFTs (G1, S2), and (G2, S2) located on the opposite sides of the source line S2 carry a negative polarity. According to the 2-dot inversion method, 2 dots (2 pixel units) are used as an inversion unit, and thus it has a better capability of reducing the flicker phenomenon.

Please referring to FIG. 1 again, the number of the gate lines on the TFT array substrate 100 with dual gate design is twice as many as that with single gate design, while the number of the source lines on the TFT array substrate with dual gate design is reduced by half. Therefore the charge time of each of the TFTs connected to the gate lines is also reduced by half, and that consequently causes the inconsistence of the charge ability of the adjacent pixels with the same polarity. For instance, when a positive and a negative voltage signals are inputted to the one of the source lines in sequence, voltage signals are sequentially inputted throughout the gate line G1, G2, G3, G4 to turn on and to charge the TFTs (G1, S1), (G2, S1), (G3, S1) and (G4, S1) in sequence. Since the TFTs (G1, S1) and (G2, S1) share the source line S1, the TFT (G1, S1) electrically connected to the gate line G1 is charged prior to the TFT (G2, S1) electrically connected to the gate line G2. Similarly, the TFT (G3, S1) electrically connected to the gate line G3 is charged prior to the TFT (G4, S1) electrically connected to the gate line G4. Therefore, the charge sequence of those TFTs located on any two rows of the source line S1 may be described as a “Z” pattern. As mentioned above, because the number of the gate lines on the dual-gate type display substrate 100 is doubled, the charge time of the TFTs is reduced by half. As a result, a portion of the TFTs, such as the TFTs located on the left side of one of the source lines S1, S2 . . . Sn, which are charged earlier, are incapable of obtaining sufficient charge time to rotate the liquid crystal molecules toward the required direction, thereby causing the leakage of light. On the other hand, the other portion of the TFTs, such as the TFTs located on the right side of the source lines S1, S2 . . . Sn, which are charged later, are capable of obtaining sufficient charge time to rotate the liquid crystal molecules toward the required direction, thereby eliminating the leakage of light. Accordingly, alternately arranged bright and dark vertical stripes would appear as shown in FIG. 2 when 2-dot inversion driving method is adopted, and it is easy for the users to see the bright (denoted by “B”) and dark (denoted by “D”) vertical stripes.

Please refer to FIG. 3. FIG. 3 is a schematic diagram illustrating a black matrix disposed on the color filter substrate of a conventional dual-gate type display panel. As mentioned above, the number of the source lines on the dual-gate type display panel is reduced by half, and thus the source lines are not disposed between any two adjacent pixel units along a direction of the gate lines on the TFT array substrate 100. Specifically, when a source line is disposed between two adjacent pixel units, no source line is disposed between one of the two pixel units and another adjacent pixel unit. Therefore, the black matrix 110, which is disposed on the color filter array substrate for preventing the leakage of light, is designed with two different widths: the black matrix 110 with wider widths are positioned corresponding to regions of the TFT array substrate 100 where the source lines are disposed, and the black matrix 110 with narrower widths are positioned corresponding to regions of the TFT array substrate 100 where no source lines are disposed. In other words, the visual bright and dark vertical stripes are easily seen due to the corresponding wide-and-narrow widths design of the black matrix 110.

Finally, please refer to FIG. 4A and FIG. 4B. FIG. 4A and FIG. 4B are schematic diagrams illustrating a TFT region of the conventional dual display panel. As mentioned before, the number of the source lines S1, S2, S3 is reduced by half, and each TFT 120 with the same polarity separately located on the opposite sides of one of the source lines S1, S2, S3. Ideally, each of the TFTs 120 has identical gate-drain capacitor (Cgd). In other words, the overlap area between the gate electrode 122 and the drain electrode 124 of each TFT 120 as marked by circle A should be the same. However, when misalignment of respective layers occurs in processing as shown in FIG. 4B, that probably causes the inconsistence of the overlap areas between the gate electrode 122 and the drain electrode 124 of the TFTs 120 separately located on the opposite sides of the same source lines, and further causes the variation of the Cgd and the feedback voltage, as well as the appearance of flicker phenomenon. To get rid of the drawback, several designs for Cgd compensation have been developed in prior art. When the overlap area between the gate electrode 122 and the drain electrode 124 increases (i.e. Cgd increases) due to process misalignment as the circle A shown in FIG. 4B, the overlap area of the capacitance compensation design as the circle B shown in FIG. 4B will become smaller correspondingly due to process misalignment. Consequently, the total capacitance may remain the same. Similarly, when the overlap area between the gate electrode 122 and the drain electrode 124 decreases (i.e. Cgd decreases) due to process misalignment, the overlap area of the capacitance compensation design will become larger correspondingly due to process misalignment. Consequently, the total capacitance may still remain the same. Although the conventional technique utilizes the capacitance compensation design to avoid the variation of Cgd of the TFTs separately located on the opposite sides of one of the source line of the dual-gate type display panel, this method is criticized for the higher cost due to its complicated processing.

Therefore, a new LCD panel design is still required to solve the problem of bright and dark vertical stripes without increasing the complexity and the cost in processing, and to maintain the consistency of Cgd of the TFTs.

### SUMMARY OF THE INVENTION

The present invention provides a TFT array substrate with dual gate design to eliminate bright and dark vertical stripes, and to solve the variation of Cgd of the TFTs due to process misalignment.

In accordance with the present invention, a TFT array substrate is provided. The TFT array substrate comprises a substrate comprising a plurality of pixel units, a plurality of first gate lines and a plurality of second gate lines alternately arranged on the substrate, and a plurality of source lines disposed on the substrate and perpendicular to the first gate lines and the second gate lines. Each of the source lines includes a main source line and a sub source line electrically connected to each other in parallel connection. Moreover, the pixel units on the substrate are arranged in a matrix, and each TFT is located in one of the pixel units respectively.

In accordance with the present invention, another TFT array substrate is provided. The TFT array substrate comprises a substrate comprising a plurality of driving units arranged in a matrix. Each of the driving units comprises a first gate line, a second gate line, a third gate line and a fourth gate line; a source line; a first TFT and a second TFT; and a third TFT and a fourth TFT. The first gate line, the second gate line, the third gate line and the fourth gate line are deposed on the substrate and arranged in parallel. The source line is deposed on the substrate and arranged perpendicularly to the first gate line, the second gate line, the third gate line and the fourth gate line. The source line comprises a main source line and a sub source line arranged in parallel and connected in parallel. The first TFT and the second TFT are located between the first gate line and the second gate line from left to right. The third TFT and the fourth TFT are located between the third gate line and the fourth gate line from left to right.

In accordance with the TFT array substrate of the present invention, the source line comprises a main source line and a sub source line connected in parallel. By altering the charge sequence of the TFTs located on the same source line, the arrangement of bright and dark pixel units produced due to the different charge ability of each TFT can be changed. Therefore, the brightness variation can be averaged to avoid the appearance of bright and dark vertical stripes, as a result, the quality of display can be promoted.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are diagrams illustrating a TFT array substrate of a conventional normal white display panel with dual gate design.

FIG. 3 is a diagram illustrating a black matrix on the color filter array substrate of a conventional display panel with dual design.

FIG. 4A and FIG. 4B are diagrams illustrating one of TFTs of a display panel with conventional dual gate design.

FIG. 5 and FIG. 6 are diagrams illustrating a TFT array substrate with dual gate design of the preferred embodiment of the present invention.

FIG. 7 is a diagram illustrating a TFT located on the TFT array substrate 200 of the preferred embodiment.

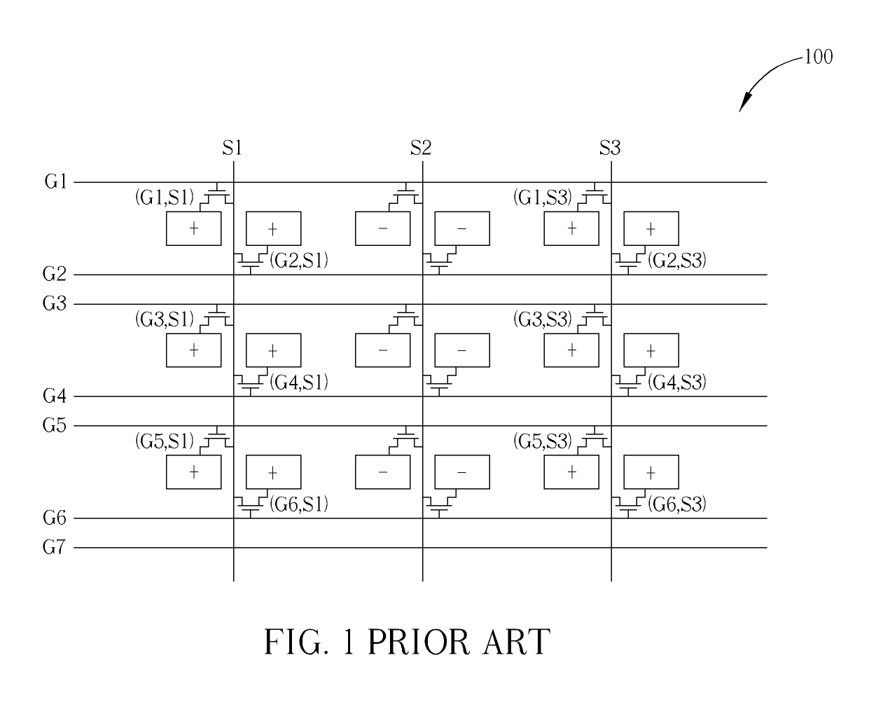

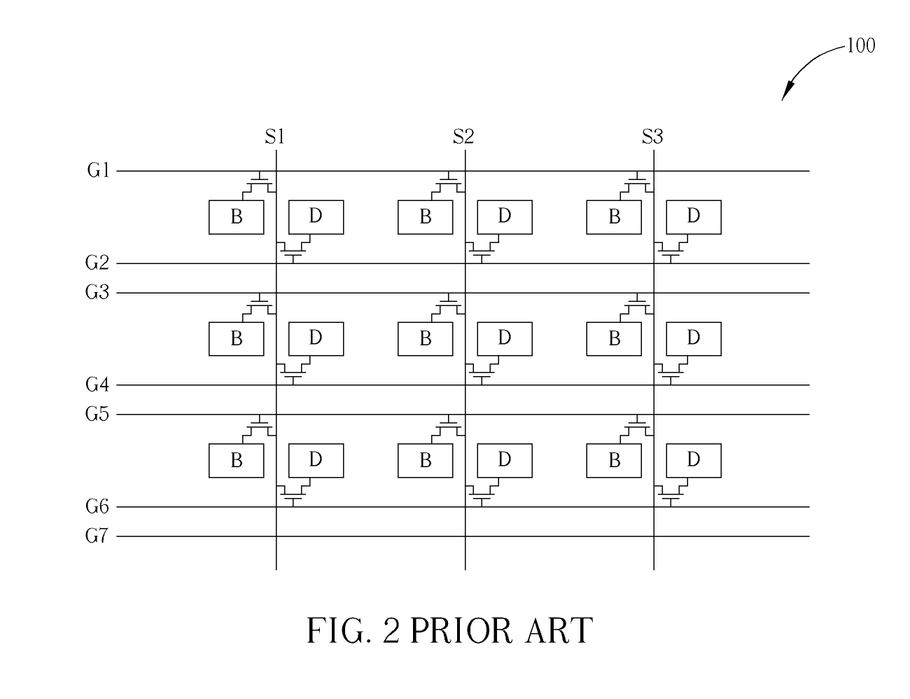

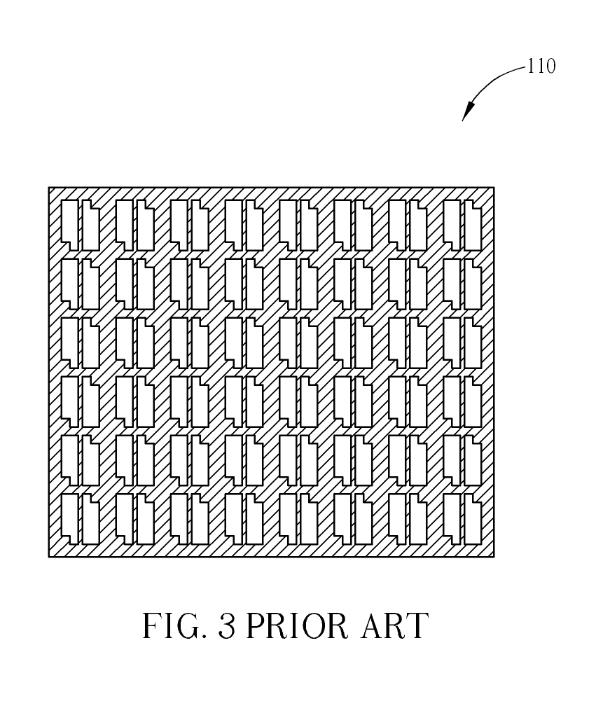

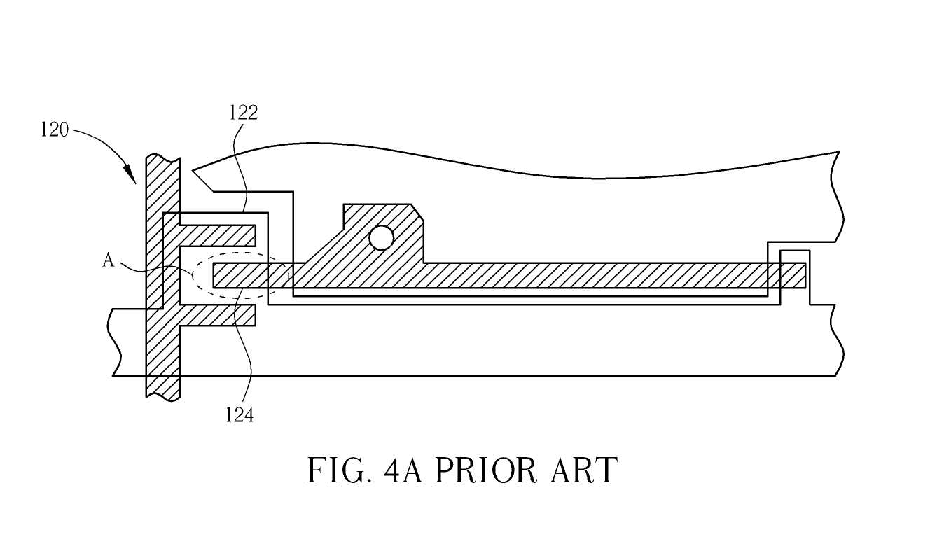

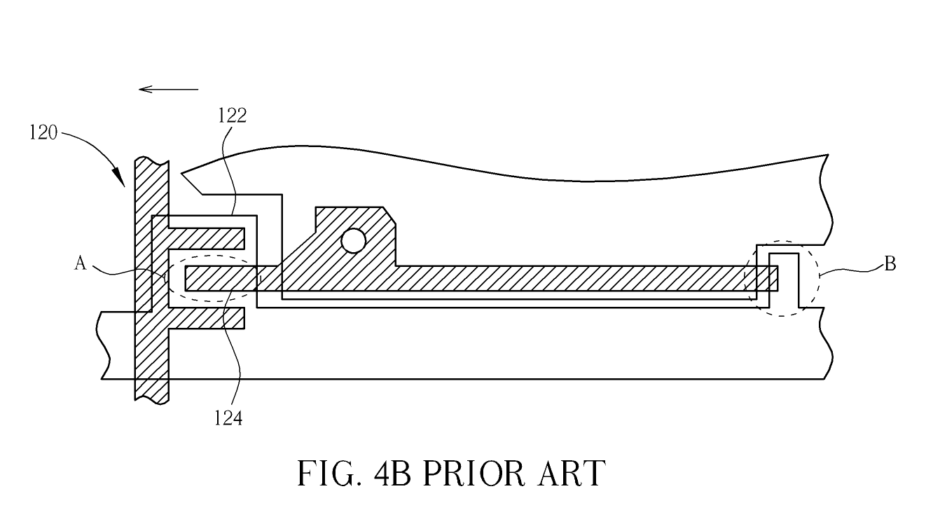

### DETAILED DESCRIPTION

Certain terms are used throughout the description and following claims to refer to particular components. As one skilled in the art will appreciate, manufacturers may refer to a component by different names. This document does not intend to distinguish between components that differ in name but in function. In the following discussion and in the claims, the terms “include”, “including”, “comprise”, and “comprising” are used in an open-ended fashion, and thus should be interpreted to mean “including, but not limited to . . . ” The terms “electrically connect” and “electrically connected” are intended to mean either an indirect or a direct electrical connection. Thus, if a first device electrically connects a second device, that connection may be through a direct electrical connection, or through an indirect electrical connection via other panels and connections.

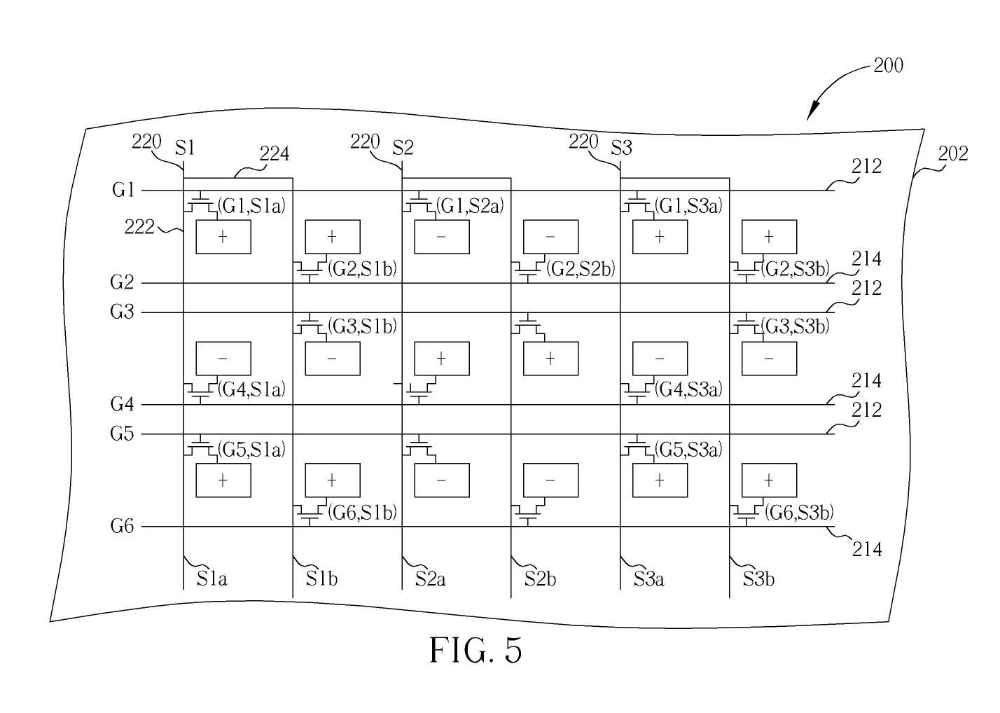

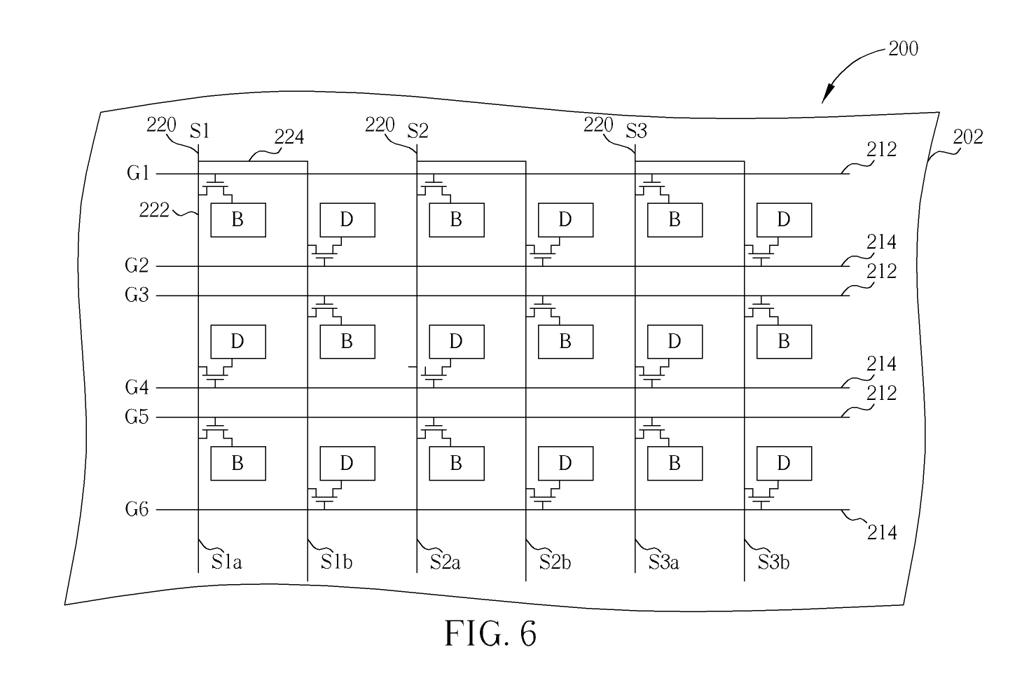

Please refer to FIG. 5 and FIG. 6. FIG. 5 and FIG. 6 are diagrams illustrating a TFT array substrate with dual gate design of a preferred embodiment. The TFT array substrate is one of the components of an LCD panel, and the LCD panel further comprises a color filter array substrate opposite to the TFT array substrate, and a liquid crystal layer positioned between the TFT array substrate and the color filter array substrate. The detail structures of the color filter array substrate and the liquid crystal layer is well known to those skilled in the art, and thus is not redundantly described. Referring to FIG. 5, the TFT array substrate 200 of the preferred embodiment comprises a substrate 202, wherein the substrate 202 comprises a plurality of first gate lines 212 and a plurality of second gate lines 214 arranged in parallel and positioned alternately on the substrate 202. Additionally, the first gate lines 212 and the second gate lines 214 can be labeled as G1, G2, . . . , G6 according to the sequence from top to bottom. The substrate 202 further comprises a plurality of source lines 220 perpendicular to the first gate lines 212 and the second gate lines 214 on the substrate 202. Each of the source lines 220 respectively comprises a main source line 222 and a sub source line 224 arranged and electrically connected in parallel. Since the main source line 222 and the sub source line 224 of one of the source lines 220 are electrically connected in parallel, the main source line 222 and the sub source line 224 of one of the source lines 220 receive the same voltage signal. Furthermore, each of the source lines 220 can be labeled as S1, S2, S3 from left to right, wherein each of the main source lines 222 can be labeled as S1a, S2a, S3a; and each of the sub source lines 224 can be labeled as S1b, S2b, S3b. In addition, the TFT array substrate 200 further includes a plurality of TFTs (G1, S1a), (G2, S1b), . . . , (G5, S3a), . . . , (G6, S3b) respectively located on the intersections of the gate lines including the first gate lines 212 and the second gate lines 214 and the source lines including the main source lines 222 and the sub source lines 224, and each of the TFTs is respectively located in a corresponding pixel unit. As shown in FIG. 5, the TFTs (G1, S1a), (G2, S1b), . . . , (G5, S3a), . . . , (G6, S3b) are arranged in a matrix and located on the substrate 202.

As mentioned above, the TFTs (G1, S1a), (G2, S1b), . . . , (G5, S3a), . . . , (G6, S3b) are arranged in a matrix and located on the substrate 202, therefore the definitions of “row” and “column” are used throughout the following description for identifying the configurations of each TFT array substrate 200 of the preferred embodiment. Referring to FIG. 5, the TFT array substrate 200 of the preferred embodiment comprises a plurality of odd-column TFTs (G1, S1a), (G4, S1a), (G5, S1a), . . . , (G1, S3a), (G4, S3a), (G5, S3a) and a plurality of even-column TFTs (G2, S1b), (G3, S1b), (G6, S1b), . . . , (G2, S3b), (G3, S3b), (G6, S3b). Each odd-column TFT is located between the main source lines 222 and the sub source lines 224 of one of the source lines 220, and each even-column TFT is located between the sub source line 224 of an adjacent source line 220 and the main source line 222 of one of the source lines 220. It is appreciated that in the preferred embodiment, each of the odd-column TFTs (G1, S1a), (G4, S1a), (G5, S1a), . . . , (G1, S3a), (G4, S3a), (G5, S3a) is electrically connected to one of the main source lines 222 respectively; and each of the even-column TFTs (G2, S1b), (G3, S1b), (G6, S1b), . . . , (G2, S3b), (G3, S3b), (G6, S3b) is electrically connected to one of the sub source lines 224 respectively. Since the preferred embodiment utilizes 2-dot inversion driving method, the TFTs and the pixel units located on the same row and electrically connected to the same source line 220, such as the TFTs (G1, S1a) and (G2, S1b) electrically connected to the main source lines 222 and the sub source lines 224 of the same source line 220, carry a positive polarity. On the other hand, the TFTs located on the same row and electrically connected to two adjacent source lines 220 carry opposite polarities, for example, the TFTs (G1, S1a) and (G2, S1b) electrically connected to the source line S1 carry a positive polarity, while the TFTs (G1, S2a) and (G2, S2b) electrically connected the source line S2 carry a negative polarity. Additionally, each of the TFTs sharing the same source line 220 and located on the next row carries an opposite polarity with respect to that located on the previous row. For example, the TFTs (G1, S1a) and (G2, S1b) disposed on the first row and electrically connected to the source line S1 (comprising the main source line S1a and the sub source line S1b) carry a positive polarity; and the TFTs (G4, S1a) and (G3, S1b) disposed on the second row and electrically connected to the source line S1 carry a negative polarity.

The TFT array substrate 200 of the preferred embodiment comprises a plurality of odd-column TFTs (G1, S1a), (G4, S1a), (G5, S1a), . . . , (G1, S3a), (G4, S3a), (G5, S3a) and a plurality of even-column TFTs (G2, S1b), (G3, S1b), (G6, S1b), . . . , (G2, S3b), (G3, S3b), (G6, S3b). It is noted that in the preferred embodiment, each of the odd-row TFTs is electrically connected to the first gate line 212 and the second gate line 214 from left to right alternately in sequence; on the contrary, each of the even-row TFTs is electrically connected to the second gate line 214 and the first gate line 212 from left to right alternately in sequence.

Additionally, if four TFTs electrically connected to the four gate lines G4m+1, G4m+2, G4m+3 and G4m+4 and located aside the source line Sn (comprising a main source lines Sna and a sub source lines Snb) are regarded as a driving unit, the four TFTs of the driving unit are respectively located on the four quadrants of a 2*2 array, where “m” is an integer larger than or equal to 0, and “n” is an integer larger than 1. The TFT (G4m+1, Sna) and the TFT (G4m+2, Snb) are located between the gate line G4m+1 and the gate line G4m+2, and electrically connected to the gate line G4m+1 and the gate line G4m+2 respectively; the TFT (G4m+4, Sna) and the TFT (G4m+3, Snb) are located between the gate line G4m+3 and the gate line G4m+4 and electrically connected to the gate line G4m+4 and the gate line G4m+3 respectively. Also, the sub source lines Snb is located between the TFT (G4m+1, Sna) and the TFT (G4m+2, Snb); and also between the TFT (G4m+3, Sna) and the TFT (G4m+4, Snb).

Please refer to FIG. 6. A configuration of the driving unit in which “m” is set as 0 and “n” is set as 1 is taken as an example. When positive and negative voltage signals are inputted to the same source lines S1, the gate lines G1, G2, G3, G4 are also provided with voltage signals sequentially to turn on and charge the TFTs (G1, S1a), (G2, S1b), (G3, S1b) and (G4, S1a) in sequence. Because the TFTs (G1, S1a) and (G2, S1b) share the main source line 222 and the sub source line 224 of the same source line S1, the TFT (G1, S1a) electrically connected to the gate line G1 is charged prior to the TFT (G2, S1b) electrically connected to the gate line G2; similarly, the TFT (G3, S1b) electrically connected to the gate line G3 is charged prior to the TFT (G4, S1a) electrically connected to the gate line G4. Briefly, the charge sequence of the TFT of any one of the driving unit may be described as an “inversed C” pattern.

As mentioned above, the number of the gate lines on the dual gate TFT array substrate 200 is doubled, therefore the charge time of those TFTs is reduced by half. As a result, a portion of the TFTs, such as the TFTs located on odd-rows, electrically connected to the first gate lines 212 and charged earlier, are incapable of obtaining sufficient charge time to rotate the liquid crystal molecules toward the required direction, which would cause the leakage of light. The TFTs located on odd-rows, electrically connected to the second gate lines 214 and charged later, however, are capable of obtaining sufficient charge time to rotate the liquid crystal molecules toward the required direction, which may eliminate the leakage of light. In the same way, the TFTs located on even-rows, electrically connected to the first gate lines 212 and charged earlier, are incapable of obtaining sufficient charge time to rotate the liquid crystal molecules toward the required direction, which would cause the leakage of light. The TFTs located on even-rows, electrically connected to the second gate lines 214 and charged later, are capable of obtaining sufficient charge time to rotate the liquid crystal molecules toward the required direction, which may eliminate the leakage of light. In accordance with the TFT array substrate 200 of the preferred embodiment, even though the pixel units with the same polarity have different brightness due to their different charge abilities, the brightness difference may be averaged because the pixel units having bright image and dark images are arranged as a dot matrix, instead of alternately arranged by lines as shown in FIG. 6. Consequently, the difference in brightness is unobvious to the users.

It is to be appreciated that each of the source lines 220 on the TFT array substrate 200 of the preferred embodiment includes a main source line 222 and a sub source line 224 electrically connected to each other in parallel, therefore, either a main source line 222 or a sub source line 224 is disposed between any two adjacent pixel units. Accordingly, the black matrix (not shown) used for preventing the leakage of light is designed with the same width corresponding to each of the main source lines 222 and the sub source lines 224. As a result, the users can hardly see bright and dark vertical stripes.

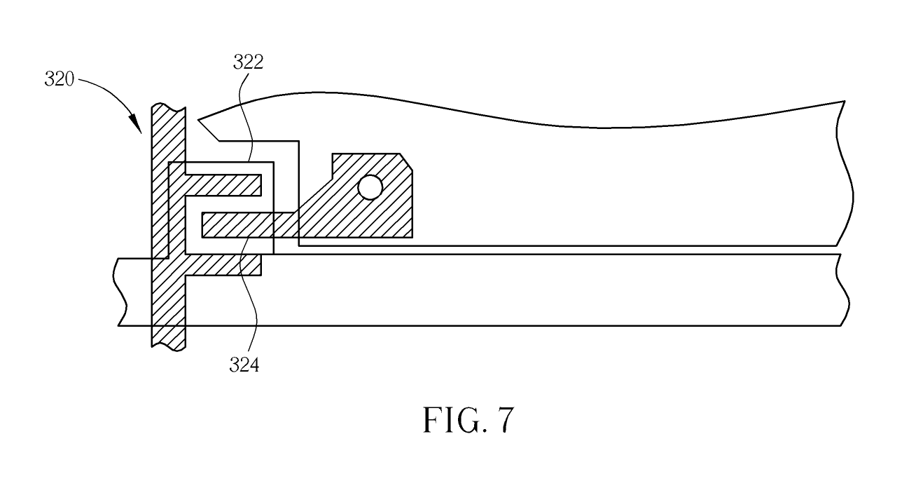

Finally, please refer to FIG. 5 and FIG. 7. FIG. 7 is a schematic diagram illustrating a TFT region of the TFT array substrate 200 of the preferred embodiment. The source lines 220 of the preferred embodiment includes a main source line 222 and a sub source line 224, and two TFTs with the same polarity as shown in FIG. 5 is electrically connected to the main source line 222 and the sub source line 224 respectively. The two TFTs are located on the same side of the main source line 222 and the sub source line 224, rather than on two opposite sides of the main source line 222 and the sub source line 224. For instance, the two TFTs may be located on the right side of the main source line 222 and the sub source line 224 as shown in FIG. 5, or on the left side of the main source line 222 and the sub source line 224. As a result, even when misalignment of the corresponding layers occurs in processing, the effects of the overlap area between the gate electrode 322 and the drain electrode 324 of each TFT 320 due to the misalignment are totally the same. Therefore, the Cgd of each TFT 320 maintains the same. Consequently, the design of Cgd compensation for the TFT array substrate 200 is not required in the preferred embodiment as shown in FIG. 7, and this lowers the complexity in processing and save the fabrication cost.

To sum up, in accordance with the TFT array substrate of the present invention, each source line includes a main source line and a sub source line connected in parallel; also, by altering the charge sequence of the TFTs electrically connected to the same source line, the arrangement of the pixel units having bright image or dark image duo to different charge abilities is also changed. As a result, the present invention is capable of averaging the variation of brightness and avoiding the appearance of bright and dark vertical stripes to promote the quality of display. Additionally, the black matrix used for preventing light leakage is designed with the same widths corresponding to each one of the main source lines and the sub source lines, which is capable of eliminating the bright and dark vertical stripes. Finally, owing to the design of the sub source lines, each TFT can be located on the same side of the main source line and the sub source line; therefore, even when misalignment occurs in processing, the effects of the Cdg variation on each TFT still maintain the same. Consequently, the design of Cgd compensation can be omitted. Briefly, the TFT array substrate with dual gate design of the present invention is capable of solving the problem of the appearance of the bright and dark vertical stripes and maintaining the Cgd of each TFT without increasing the complexity and the fabrication cost.

Those skilled in the art will readily observe that numerous modifications and alterations of the device and method may be made while retaining the teachings of the invention.

What is claimed is:

1. A TFT array substrate, comprising:
a substrate comprising a plurality of pixel units arranged in a matrix;
a plurality of first gate lines and a plurality of second gate lines disposed on the substrate, the first gate lines and the second gate lines being arranged alternately;
a plurality of source lines disposed on the substrate and perpendicular to the first gate lines and the second gate lines, wherein each of the source lines further includes a main source line and a sub source line electrically connected to each other in parallel connection; and
a plurality of TFTs respectively positioned in the pixel units.

2. The TFT array substrate of claim 1, wherein the TFTs are arranged in a matrix.

3. The TFT array substrate of claim 2, wherein the TFTs comprises a plurality of odd-column TFTs and a plurality of even-column TFTs.

4. The TFT array substrate of claim 3, wherein each of the odd-column TFTs is located between the main source line and the sub source line of the same source line respectively; and each of the even-column TFTs is located between the main source line of one of the source lines and the sub source line of the adjacent source line respectively.

5. The TFT array substrate of claim 3, wherein each of the odd-column TFTs is electrically connected to the main source line of the source line respectively; and each of the even-column TFTs is electrically connected to the sub source line of the source line respectively.

6. The TFT array substrate of claim 2, wherein the TFT array substrate comprises a plurality of odd-row TFTs and a plurality of even-row TFTs.

7. The TFT array substrate of claim 6, wherein each of the odd-row TFTs is electrically connected to the first gate line and the second gate line in sequence, and each of the even-row TFTs is electrically connected to the second gate line and the first gate line in sequence.

8. A TFT array substrate, comprising:
a substrate, comprising a plurality of driving units arranged in
a matrix, wherein the driving unit comprises:
a first gate line, a second gate line, a third gate line and a fourth gate line deposed on the substrate and arranged parallel to each other;
a source line, deposed on the substrate and arranged perpendicularly to the first gate line, the second gate line, the third gate line and the fourth gate line, wherein the source line comprises a main source line and a sub source line arranged in parallel and connected in parallel;
a first TFT and a second TFT, located between the first gate line and the second gate line from left to right; and
a third TFT and a fourth TFT, located between the third gate line and the fourth gate line from left to right.

9. The TFT array substrate of claim 8, wherein each of the sub source lines is located between the first TFT and the second TFT, and also located between the third TFT and the fourth TFT.

10. The TFT array substrate of claim 8, wherein each of the first TFTs and the second TFTs is electrically connected to the first gate line and the second gate line respectively, and each of the third TFTs and the fourth TFTs is electrically connected to the fourth gate line and the third gate line respectively.
